(19) United States
(12) Patent Application Publication
(10) Pub. No.: US 2015/0109749 A1
(43) Pub. Date: Apr. 23, 2015

(54) CIRCUIT BOARD ASSEMBLY, WIRE FIXING DEVICE AND WIRE FIXING METHOD

(71) Applicant: DELTA ELECTRONICS, INC., TAOYUAN HSIEN (TW)

(72) Inventors: Ching-Ho Chou, Taoyuan Hsien (TW); Do Chen, Taoyuan Hsien (TW); Shang-Yu Li, Taoyuan Hsien (TW); Chun-Jen Chung, Taoyuan Hsien (TW)

(73) Assignee: DELTA ELECTRONICS, INC., TAOYUAN HSIEN (TW)

(21) Appl. No.: 14/243,465

(22) Filed: Apr. 2, 2014

(30) Foreign Application Priority Data
Oct. 18, 2013 (TW) 102137781

(51) Int. Cl. H05K 1/11; H05K 3/10

(52) U.S. Cl. CPC H05K 1/116; H05K 3/10
USPC 361/772; 29/745; 29/850

(57) ABSTRACT

A circuit board assembly includes a printed circuit board, at least one wire, at least one wire fixing device, and a plurality of electronic components. A wire fixing method includes following steps. Firstly, the wire fixing device is inserted into a conductive hole of the printed circuit board. Then, the wire fixing device is fixed on the printed circuit board via a soldering material. Then, a conducting terminal of the wire is introduced into an accommodation space of the wire fixing device through the first opening of the wire fixing device. Then, at least one concave structure is formed in an external surface of a first conducting part of the wire fixing device by a jig. Consequently, the conducting terminal of the wire is fixed on the wire fixing device, and the wire is electrically connected with the printed circuit board through the wire fixing device.

### FIELD OF THE INVENTION

The present invention relates to a wire fixing device and a wire fixing method, and more particularly to a wire fixing device and a wire fixing method for fixing a wire on a printed circuit board and electrically connecting the wire with the printed circuit board. The present invention also relates to a circuit board assembly with the wire fixing device.

### BACKGROUND OF THE INVENTION

Electronic ballast is widely used in a lighting device for driving illumination of a light source of the lighting device. Generally, the electronic ballast comprises a casing and a circuit board assembly. The circuit board assembly is disposed in the casing and comprises a printed circuit board, a plurality of electronic components, and a plurality of wires. The electronic components are mounted on the printed circuit board. The wires are fixed on the printed circuit board. Through the wires, the circuit board assembly of the electronic ballast can be electrically connected with the lighting device.

In accordance with a conventional wire fixing method, a conducting terminal (i.e. a bare wire terminal) of the wire is directly inserted into a corresponding conductive hole of the printed circuit board, and then the wire and the printed circuit board are transferred through a reflow furnace together. Consequently, the wire is fixed on the printed circuit board via a soldering material. However, when the wire and the printed circuit board are transferred through the reflow furnace together, the wire is readily suffered from damage because of the high temperature. Under this circumstance, the resistance of the wire increases, and the tensile strength of the wire decreases. Since the wire is usually pulled by external forces and the wire is fixed on the printed circuit board only via the soldering material, the conducting terminal of the wire is easily broken or detached from the printed circuit board.

For solving the above drawbacks, a wire fixing method was disclosed in for example U.S. Pat. No. 7,182,655. The wire fixing method uses a barrel pin to fix the wire on the printed circuit board. FIGS. 1A-1F schematically illustrate a conventional wire fixing method. Firstly, as shown in FIG. 1A, a wire fixing device 12 (i.e. a barrel pin) is provided. Then, as shown in FIG. 1B, the barrel pin 12 is inserted into a corresponding conductive hole 11a of a printed circuit board 11. Then, as shown in FIG. 1C, a bottom end 12a of the barrel pin 12 is riveted to a bottom surface of the printed circuit board 11 by a first jig (not shown). Then, the barrel pin 12 and the printed circuit board 11 are transferred through a reflow furnace (not shown) together. Consequently, the bottom end 12a of the barrel pin 12 is fixed on the printed circuit board 11 via a soldering material 14, and the barrel pin 12 is fixed on and electrically connected with the printed circuit board 11 (see FIG. 1D). The, as shown in FIG. 1E, a conducting terminal 13a (i.e. a bare wire terminal) of a wire 13 is directly inserted into the barrel pin 12. Afterwards, a plurality of recesses 12b are formed in the sidewall of the barrel pin 12 by a second jig 15. Consequently, the wire 13 can be fixed on and electrically connected with the barrel pin 12. By the above wire fixing method, the wires 13 may be fixed on and electrically connected with the printed circuit board 11 through the barrel pins 12. Consequently, a circuit board assembly 1 is formed.

However, the conventional wire fixing method still has some drawbacks. For example, since two jigs are used to process the barrel pin 12, the conventional wire fixing method is complicated, time-consuming and labor-intensive. In addition, the product yield is usually unsatisfied. Moreover, since the bottom end 12a of the barrel pin 12 is riveted to the bottom surface of the printed circuit board 11 by the first jig, the soldering area on the bottom surface of the printed circuit board 11 should be large enough. Under this circumstance, the circuitry layout of the printed circuit board 11 is influenced.

Please refer to FIG. 1D. The barrel pin 12 is substantially a cylindrical hollow tube. When the barrel pin 12 and the printed circuit board 11 are transferred through the reflow furnace together, a portion of the molten soldering material 14 is introduced into the barrel pin 12 through a bottom opening of the barrel pin 12 (not shown), and formed within an accommodation space 12c inside the barrel pin 12. In other words, a solder-gushing phenomenon occurs. Under this circumstance, the accommodation space 12c inside the barrel pin 12 is insufficient to accommodate the conducting terminal 13a of the wire 13, so that the wire 13 fails to be fixed by the barrel pin 12. For avoiding the occurrence of the solder-gushing phenomenon, the barrel pin 12 is previously nickel-plated. As known, the nickel-plating treatment may increase the fabricating cost and cause poor solderability of the bottom end 12a of the barrel pin 12. Consequently, the barrel pin 12 cannot be firmly fixed on the printed circuit board 11.

Moreover, the barrel pin 12 has a neck structure 12d (see FIG. 1A). The neck structure 12d is protruded from an external surface of the barrel pin 12, and produced by an extrusion process. Since wall thicknesses of the top edge and the bottom edge of the neck structure 12d are relatively thin, if an external force is exerted on the barrel pin 12, the centralized stress may cause fracture of the barrel pin 12. Under this circumstance, the wire 13 is detached from the printed circuit board 11.

Therefore, there is a need of providing a circuit board assembly, a wire fixing device and a wire fixing method in order to eliminate the above drawbacks.

### SUMMARY OF THE INVENTION

The present invention provides a circuit board assembly, a wire fixing device and a wire fixing method. By the wire fixing device, a wire is fixed on and electrically connected with a printed circuit board. When the wire fixing device and the printed circuit board are transferred through a reflow furnace together, the solder-gushing phenomenon is minimized or avoided. Moreover, the soldering area on the bottom surface of the printed circuit board is reduced, so that the circuitry layout of the printed circuit board can be designed with more space. Moreover, the structural strength of the wire fixing device is enhanced, so that the possibility of causing fracture of the wire fixing device by the centralized stress is minimized. According to the present invention, the frequency of using the jig is reduced, the fabricating process is simplified, the fabricating cost is reduced, and the throughput and the yield are enhanced.

In accordance with an aspect of the present invention, there is provided a circuit board assembly. The circuit board assembly includes a printed circuit board, a plurality of electronic components, at least one wire, and at least one wire fixing device. The printed circuit board has a first surface and a second surface. In addition, at least one conductive hole runs through the first surface and the second surface. The electronic components are disposed on the printed circuit board. The wire has a conducting terminal. The wire fixing device is fixed on the printed circuit board and electrically connected with the at least one wire. The wire fixing device includes a first conducting part, a second conducting part, and a tip part. The first conducting part has a first opening The first conducting part has a first outer diameter. The second conducting part is connected with the first conducting part. The second conducting part has a second outer diameter. The second outer diameter is smaller than the first outer diameter. The tip part is connected with the second conducting part. The tip part is a taper structure. An accommodation space is disposed within the first conducting part, the second conducting part and the tip part and in communication with the first opening for accommodating the conducting terminal of the wire. The first conducting part is disposed over the first surface of the printed circuit board. At least a portion of the second conducting part is disposed within the conductive hole of the printed circuit board. The tip part is disposed under the second surface of the printed circuit board. A soldering material is coated on a junction between the printed circuit board and the tip part and/or the second conducting part of the wire fixing device, so that the wire fixing device is fixed on the printed circuit board.

In accordance with another aspect of the present invention, there is provided a wire fixing device. The wire fixing device is used for assisting in fixing a wire on a printed circuit board and electrically connecting the wire with the printed circuit board. The printed circuit board has a first surface and a second surface. In addition, at least one conductive hole runs through the first surface and the second surface. The wire has a conducting terminal. The wire fixing device includes a first conducting part, a second conducting part, and a tip part. The first conducting part has a first opening. The first conducting part has a first outer diameter. The second conducting part is connected with the first conducting part. The second conducting part has a second outer diameter. The second outer diameter is smaller than the first outer diameter. The tip part is connected with the second conducting part. The tip part is a taper structure. An accommodation space is disposed within the first conducting part, the second conducting part and the tip part and in communication with the first opening for accommodating the conducting terminal of the wire. The first conducting part is disposed over the first surface of the printed circuit board for fixing and connecting the conducting terminal of the wire. At least a portion of the second conducting part of the wire fixing device is snap-fitted or interference-fitted into the conductive hole of the printed circuit board. The tip part and/or the second conducting part are fixed on the second surface of the printed circuit board via a soldering material.

In accordance with a further aspect of the present invention, there is provided a wire fixing method. The wire fixing method includes the following steps. Firstly, a printed circuit board, at least one wire and a wire fixing device are provided. The printed circuit board has a first surface and a second surface, and at least one conductive hole runs through the first surface and the second surface. The wire has a conducting terminal. The wire fixing device includes a first conducting part with a first opening, a second conducting part connected with the first conducting part, and a tip part connected with the second conducting part. The first conducting part has a first outer diameter. The second conducting part has a second outer diameter. The second outer diameter is smaller than the first outer diameter. The tip part is a taper structure. An accommodation space is disposed within the first conducting part, the second conducting part and the tip part and in communication with the first opening. Then, the wire fixing device is inserted into the conductive hole of the printed circuit board. The first conducting part is disposed over the first surface of the printed circuit board. At least a portion of the second conducting part is disposed within the conductive hole of the printed circuit board. The tip part is disposed under the second surface of the printed circuit board. Then, a soldering material is coated on a junction between the printed circuit board and the tip part and/or the second conducting part of the wire fixing device, so that the wire fixing device is fixed on the printed circuit board. Then, the conducting terminal of the wire is introduced into the accommodation space of the wire fixing device through the first opening of the wire fixing device. Afterwards, at least one concave structure is formed in an external surface of the first conducting part of the wire fixing device, so that the conducting terminal of the wire is fixed on the wire fixing device and the wire is electrically connected with the printed circuit board through the wire fixing device.

The above contents of the present invention will become more readily apparent to those ordinarily skilled in the art after reviewing the following detailed description and accompanying drawings, in which:

### BRIEF DESCRIPTION OF THE DRAWINGS

FIGS. 1A-1F schematically illustrate a conventional wire fixing method;

FIG. 2 schematically illustrates a circuit board assembly according to an embodiment of the present invention;

FIG. 3A schematically illustrates an exemplary wire fixing device for the circuit board assembly of FIG. 2;

FIG. 3B schematically illustrates a portion of another exemplary wire fixing device for the circuit board assembly of FIG. 2;

FIGS. 4A and 4B schematically illustrate two exemplary profiles of the conductive hole of the printed circuit board;

FIGS. 5A-5C schematically illustrate the steps of a wire fixing method according to an embodiment of the present invention; and

FIG. 6 is a flowchart illustrating the wire fixing method according to the embodiment of the present invention.

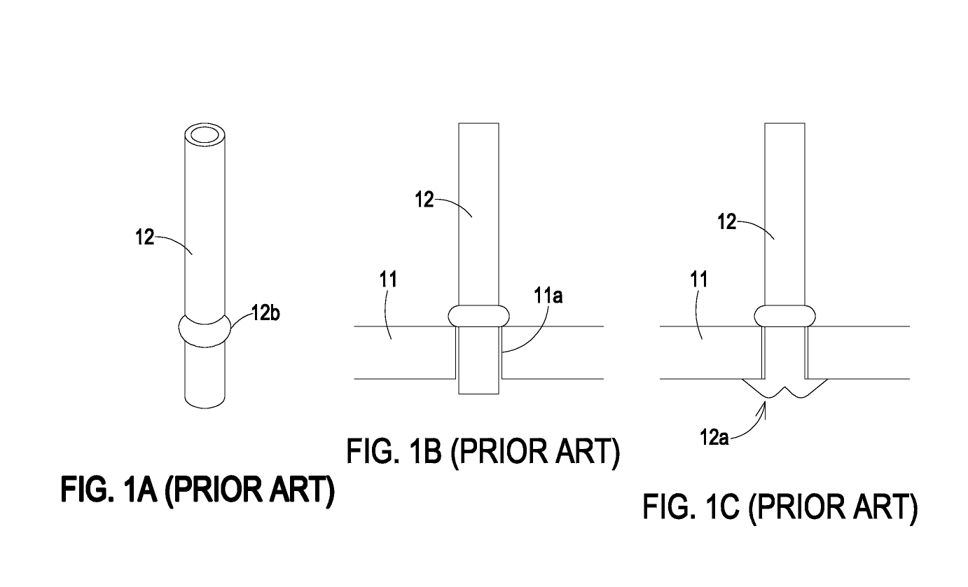

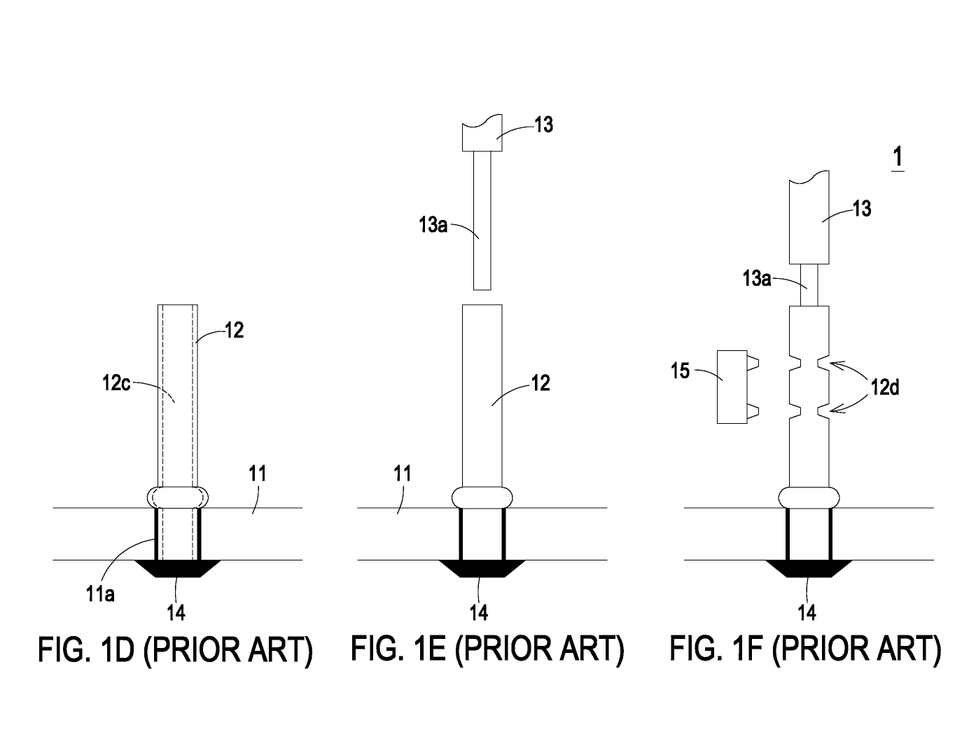

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

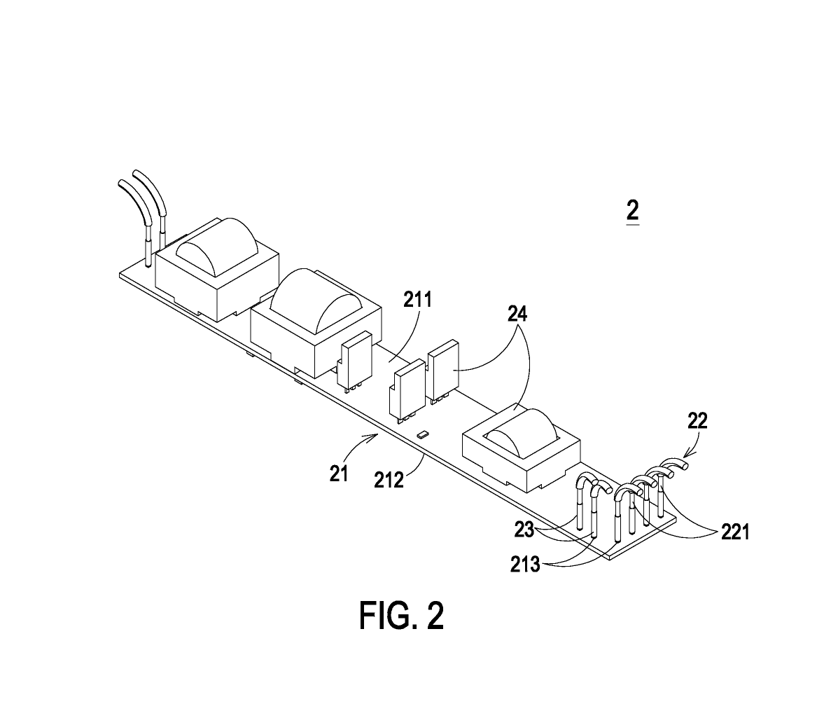

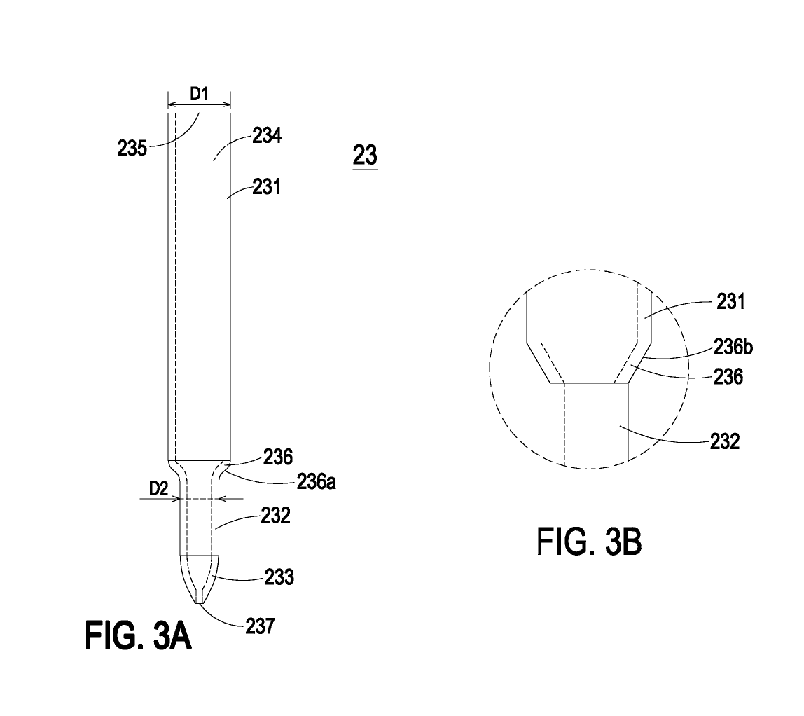

FIG. 2 schematically illustrates a circuit board assembly according to an embodiment of the present invention. FIG. 3A schematically illustrates an exemplary wire fixing device for the circuit board assembly of FIG. 2. Please refer to FIGS. 2 and 3A. The circuit board assembly 2 may be applied to electronic ballast, but is not limited thereto. The circuit board assembly 2 comprises a printed circuit board 21, at least one wire 22, at least one wire fixing device 23, and a plurality of electronic components 24. The printed circuit board 21 has a first surface 211 and a second surface 212, wherein the first surface 211 and the second surface 212 are opposed to each other. Moreover, at least one conductive hole 213 runs through the first surface 211 and the second surface 212. The wire 22 comprises an insulating cover layer and a conducting terminal 221. The conducting terminal 221 is a bare wire terminal. The electronic components 24 are disposed on the printed circuit board 21. For example, the electronic components 24 are disposed on the first surface 211 of the printed circuit board 21. Consequently, a circuit with a specified function is constituted by the printed circuit board 21 and the electronic components 24 collaboratively.

The wire fixing device 23 is made of a metallic conductive material. The wire fixing device 23 is fixed on the printed circuit board 21, and electrically connected with a corresponding wire 22. The wire fixing device 23 is used for assisting in fixing the wire 22 on the printed circuit board 21 and electrically connecting the wire 22 with the printed circuit board 21.

In this embodiment, the wire fixing device 23 comprises a first conducting part 231, a second conducting part 232, and a tip part 233. An accommodation space 234 is disposed within the first conducting part 231, the second conducting part 232 and the tip part 233 for accommodating the conducting terminal 221 of the wire 22. In particular, the accommodation space 234 runs through the first conducting part 231, the second conducting part 232 and the tip part 233, and the accommodation space 234 is used for accommodating the conducting terminal 221 of the wire 22. The first conducting part 231 has a first opening 235. The first opening 235 is in communication with the accommodation space 234. In addition, the first conducting part 231 has a first outer diameter D1.

The second conducting part 232 is connected with the first conducting part 231. In addition, the second conducting part 232 has a second outer diameter D2. The second outer diameter D2 is smaller than the first outer diameter D1. The tip part 233 is connected with the second conducting part 232. In addition, the tip part 233 is a taper structure. In other words, the outer diameter of the tip part 233 is gradually reduced from the junction between the tip part 233 and the second conducting part 232 to the free end of the tip part 233. When the wire fixing device 23 is fixed on the printed circuit board 21, the first conducting part 231 is disposed over the first surface 211 of the printed circuit board 21, at least a portion of the second conducting part 232 is snap-fitted or interference-fitted into the conductive hole 213 of the printed circuit board 21, and the tip part 233 is disposed under the second surface 212 of the printed circuit board 21. In case that a portion of the second conducting part 232 is protruded out of the conductive hole 213, a soldering material (not shown) is coated on the junction between the printed circuit board 21, the tip part 233 of the wire fixing device 23 and the second conducting part 232 of the wire fixing device 23. Whereas, in case that the second conducting part 232 is not protruded out of the conductive hole 213, the soldering material (not shown) is coated on the junction between the printed circuit board 21 and the tip part 233 of the wire fixing device 23. By means of the soldering material, the wire fixing device 23 is fixed on the printed circuit board 21.

In this embodiment, the first conducting part 231 and the second conducting part 232 are connected with each other through a connecting segment 236. For example, the connecting segment 236 is a ring-shaped structure with an external smooth curvy surface 236a. The external smooth curvy surface 236a of the connecting segment 236 is connected with the external surface of the first conducting part 231 and the external surface of the second conducting part 232. The outer diameter of the connecting segment 236 is gradually decreased from the junction between the connecting segment 236 and the first conducting part 231 to the junction between the connecting segment 236 and the second conducting part 232. Moreover, the outer diameter of the connecting segment 236 is in the range between the second outer diameter D2 and the first outer diameter D1.

FIG. 3B schematically illustrates a portion of another exemplary wire fixing device for the circuit board assembly of FIG. 2. As shown in FIG. 3B, the connecting segment 236 is a ring-shaped structure with an external slant surface 236b. The external slant surface 236b of the connecting segment 236 is connected with the external surface of the first conducting part 231 and the external surface of the second conducting part 232. The outer diameter of the connecting segment 236 is gradually decreased from the junction between the connecting segment 236 and the first conducting part 231 to the junction between the connecting segment 236 and the second conducting part 232. Moreover, the outer diameter of the connecting segment 236 is in the range between the second outer diameter D2 and the first outer diameter D1.

After the wire fixing device 23 is inserted into the conductive hole 213 of the printed circuit board 21, the connecting segment 236 is in contact with the first surface 211 of the printed circuit board 21 and the periphery of the conductive hole 213. Consequently, the first conducting part 231 is stopped from being introduced into the conductive hole 213 of the printed circuit board 21. Moreover, since the connecting segment 236 has the external smooth curvy surface 236a or the external slant surface 236b, the structural strength of the wire fixing device 23 is enhanced, and the possibility of causing fracture of the wire fixing device 23 by the centralized stress is minimized.

In some embodiments, the tip part 233 has a second opening 237. The second opening 237 is opposed to the first opening 235. The second opening 237 is in communication with the accommodation space 234. The tip part 233 is a taper structure. Moreover, the second opening 237 is located at the free end of the tip part 233. Consequently, the second opening 237 is much smaller than the first opening 235 and the conductive hole 213. Consequently, the molten soldering material cannot be considerably or quickly introduced into the accommodation space 234 through the second opening 237. Under this circumstance, the solder-gushing phenomenon is minimized. Alternatively, in some other embodiments, the free end of the tip part 233 is a close end without the second opening Since the molten soldering material cannot be introduced into the accommodation space 234, the solder-gushing phenomenon is avoided.

In some embodiments, the first conducting part 231, the connecting segment 236, the second conducting part 232 and the tip part 233 of the wire fixing device 23 are integrally formed with each other. In particular, the wire fixing device 23 is produced by extruding the metallic conductive material.

In some other embodiment, the wire fixing device 23 is previously tin-plated. That is, a tin-plated layer (not shown) is formed on the surface of the wire fixing device 23. Consequently, the electric conductivity thereof is enhanced, and the bonding efficacy of the soldering material on the wire fixing device 23 is increased. In other word, the tin-plating treatment is effective to facilitate fixing the wire fixing device 23 on the printed circuit board 21.

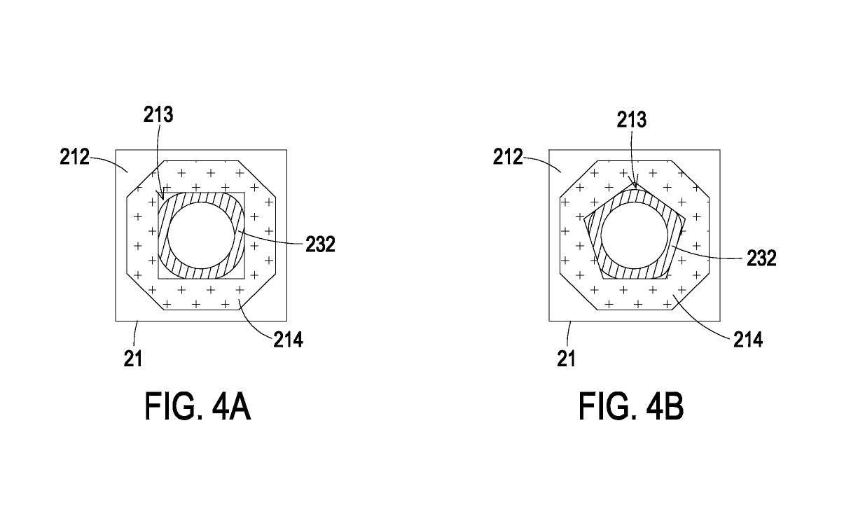

The printed circuit board 21 is a single-layered circuit board or a multilayered circuit board. In addition, the profile of the conductive hole 213 of the printed circuit board 21 may be varied according to the practical requirements. FIGS. 4A and 4B schematically illustrate two exemplary profiles of the conductive hole of the printed circuit board. Preferably, the conductive hole 213 of the printed circuit board 21 has a regular polygon profile. As shown in FIG. 4A, the conductive hole 213 of the printed circuit board 21 has a square profile. As shown in FIG. 4B, the conductive hole 213 of the printed circuit board 21 has a regular polygon profile. When the wire fixing device 23 is fixed on the printed circuit board 21, at least a portion of the second conducting part 232 is in contact with the inner surface of the conductive hole 213. Consequently, the second conducting part 232 is subject to slight deformation, and snap-fitted or interference-fitted into the conductive hole 213 of the printed circuit board 21. Due to the friction between the wire fixing device 23 and the inner surface of the conductive hole 213, the wire fixing device 23 can be fixed on the printed circuit board 21 more firmly.

Please refer to FIGS. 4A and 4B again. A bonding pad 214 is formed on the second surface 212 of the printed circuit board 21 and electrically connected with the conductive hole 213. Moreover, the bonding pad 214 is also electrically connected with the electrical traces (not shown) of the printed circuit board 21. After the soldering material (not shown) is coated on the junction between the bonding pad 214 of the printed circuit board 21, the tip part 233 of the wire fixing device 23 and a portion of the second conducting part 232 of the wire fixing device 23 or the soldering material is coated on the junction between the bonding pad 214 of the printed circuit board 21 and the tip part 233 of the wire fixing device 23, the wire fixing device 23 is fixed on and electrically connected with the printed circuit board 21. In this embodiment, the conductive hole 213 of the printed circuit board 21 has the regular polygon profile (see FIG. 4A or 4B), and the second conducting part 232 of the wire fixing device 23 has a cylindrical profile matching the profile of the conductive hole 232. When the second conducting part 232 of the wire fixing device 23 is inserted into the conductive hole 213 of the printed circuit board 21, at least a portion of the second conducting part 232 is in contact with the inner surface of the conductive hole 213, and a vacant space is formed between the second conducting part 232 and the inner surface of the conductive hole 213. Consequently, the second conducting part 232 is subject to slight deformation, and snap-fitted or interference-fitted into the conductive hole 213 of the printed circuit board 21. Moreover, since the conductive hole 213 has the regular polygon profile, the precision requirement for causing snap fit and the interference fit between the second conducting part 232 and the inner surface of the conductive hole 213 is reduced. Under this circumstance, the yield of the circuit board assembly 2 is increased, and the fabricating cost of the circuit board assembly 2 is reduced.

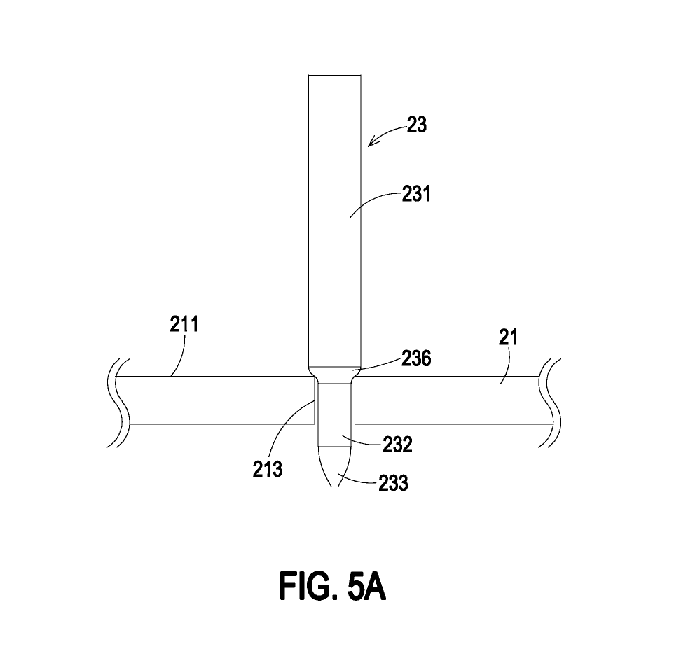

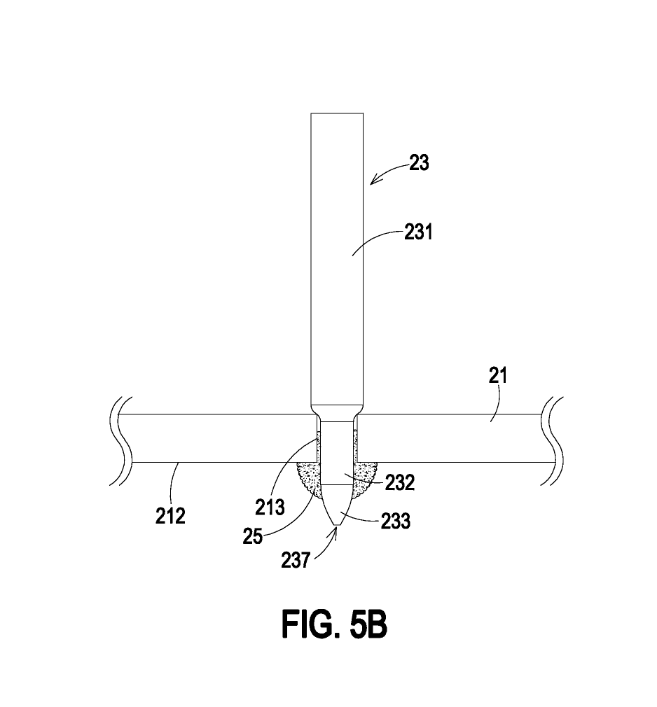

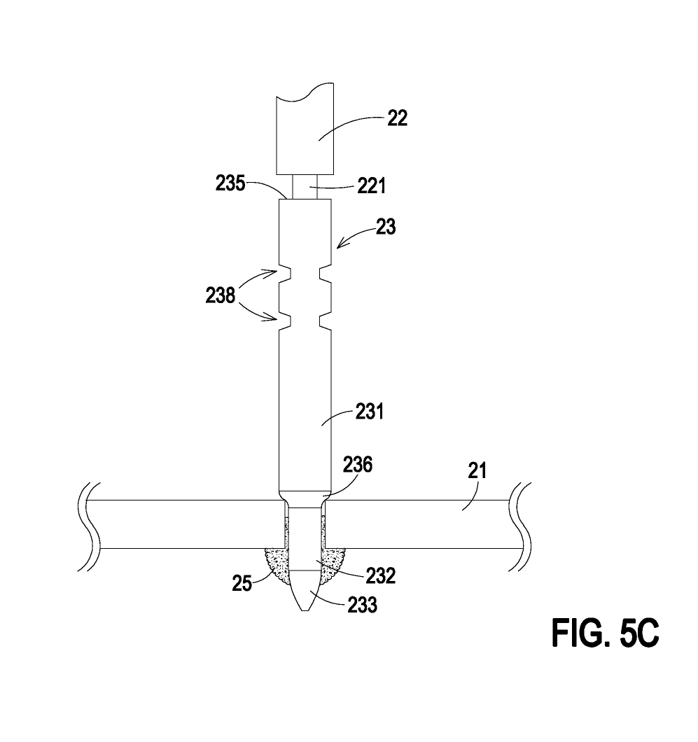

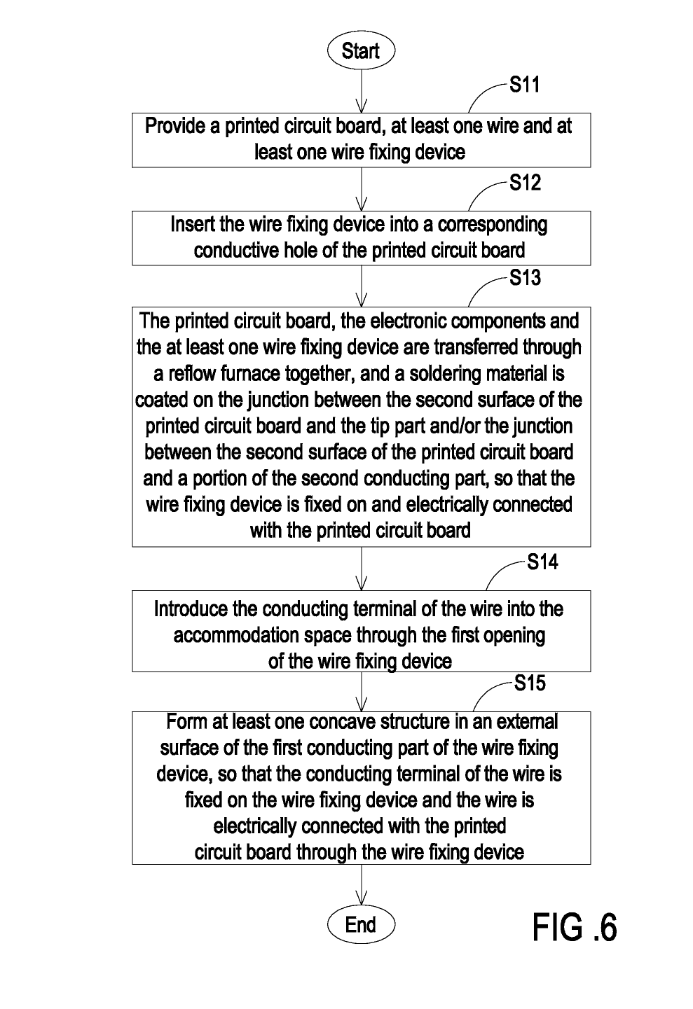

Hereinafter, a wire fixing method of the present invention will be illustrated with reference to FIG. 2, FIGS. 3A, FIGS. 5A-5C and FIG. 6. FIGS. 5A-5C schematically illustrate the steps of a wire fixing method according to an embodiment of the present invention. FIG. 6 is a flowchart illustrating the wire fixing method according to the embodiment of the present invention. Firstly, in the step S11, a printed circuit board 21, at least one wire 22 and a wire fixing device 23 are provided, wherein a plurality of electronic components 24 are disposed on the printed circuit board 21. The structures and the functions of the printed circuit board 21, the wire 22 and the wire fixing device 23 have been mentioned above, and are not redundantly described herein. Then, in the step S12, the wire fixing device 23 is inserted into a corresponding conductive hole 213 of the printed circuit board 21. Under this circumstance, the first conducting part 231 is disposed over the first surface 211 of the printed circuit board 21, the connecting segment 236 is in contact with the first surface 211 of the printed circuit board 21 and the periphery of the conductive hole 213, at least a portion of the second conducting part 232 is snap-fitted or interference-fitted into the conductive hole 213 of the printed circuit board 21, and the tip part 233 is disposed under the second surface 212 of the printed circuit board 21 (see FIG. 5A).

Then, in the step S13, the printed circuit board 21, the electronic components 24 and the at least one wire fixing device 23 are transferred through a reflow furnace together. Consequently, a soldering material 25 is coated on the junction between the second surface 212 of the printed circuit board 21, the tip part 233 of the wire fixing device 23 and a portion of the second conducting part 232 of the wire fixing device 23, or the soldering material 25 is coated on the junction between the second surface 212 of the printed circuit board 21 and the tip part 233 of the wire fixing device 23. Under this circumstance, the wire fixing device 23 is fixed on and electrically connected with the printed circuit board 21 (see FIG. 5B). In this step, the soldering material 25 may be coated on the bonding pad (not shown) of the second surface 212 of the printed circuit board 21, filled into the vacant space between the second conducting part 232 and the inner surface of the conductive hole 213, and/or coated on the tip part 233 and a portion of the second conducting part 232. Consequently, the wire fixing device 23 can be fixed on the printed circuit board 21 more firmly, and the good electrical connection between the wire fixing device 23 and the printed circuit board 21 can be established and maintained.

In case that the tip part 233 has a second opening 237, the molten soldering material 25 cannot be considerably or quickly introduced into the accommodation space 234 through the second opening 237. Under this circumstance, the solder-gushing phenomenon is minimized. Moreover, since a small amount of the soldering material 25 is introduced into the accommodation space 234, the structural strength and the weight of the wire fixing device 23 are both increased. Consequently, the possibility of causing fracture of the wire fixing device by the external force is minimized.

Then, in the step S 14, the conducting terminal 221 (i.e. the bare wire terminal) of the wire 22 is introduced into the accommodation space 234 through the first opening 235 of the wire fixing device 23. Then, at least one concave structure 238 is formed in an external surface of the first conducting part 231 of the wire fixing device 23. The conducting terminal 221 of the wire 22 inside the wire fixing device 23 is in contact with and clamped by a bottom surface of the concave structure 238. Consequently, the wire 22 is fixed on and connected with the wire fixing device 23, and the wire 22 is electrically connected with the printed circuit board 21 through the wire fixing device 23. In some embodiments, the concave structures 238 are formed in the external surface of the first conducting part 231 of the wire fixing device 23. Consequently, plural positions of the conducting terminal 221 of the wire 22 inside the wire fixing device 23 are contacted with and clamped by the bottom surfaces of the concave structures 238 (see FIG. 5C). In such way, the wire 22 is fixed on the wire fixing device 23 more securely, and the electrical connection between the wire 22 and the wire fixing device 23 is enhanced. After the wire 22 is electrically connected with the printed circuit board 21 through the wire fixing device 23, the circuit board assembly 2 of the present invention is fabricated.

From the above descriptions, the present invention provides a circuit board assembly, a wire fixing device and a wire fixing method. By the wire fixing device, a wire is fixed on and electrically connected with a printed circuit board. When the wire fixing device and the printed circuit board are transferred through a reflow furnace together, the solder-gushing phenomenon is minimized or avoided. Moreover, the soldering area on the bottom surface of the printed circuit board is reduced, so that the circuitry layout of the printed circuit board can be designed with more space. Moreover, the structural strength of the wire fixing device is enhanced, so that the possibility of causing fracture of the wire fixing device by the centralized stress is minimized. According to the present invention, the frequency of using the jig is reduced, the fabricating process is simplified, the fabricating cost is reduced, and the throughput and the yield are enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A circuit board assembly, comprising:
a printed circuit board having a first surface and a second surface, wherein at least one conductive hole runs through the first surface and the second surface;
a plurality of electronic components disposed on the printed circuit board;
at least one wire having a conducting terminal; and
at least one wire fixing device fixed on the printed circuit board and electrically connected with the at least one wire, wherein the wire fixing device comprising:
a first conducting part with a first opening, wherein the first conducting part has a first outer diameter;
a second conducting part connected with the first conducting part, wherein the second conducting part has a second outer diameter, and the second outer diameter is smaller than the first outer diameter; and
a tip part connected with the second conducting part, wherein the tip part is a taper structure,
wherein an accommodation space is disposed within the first conducting part, the second conducting part and the tip part and in communication with the first opening for accommodating the conducting terminal of the wire, wherein the first conducting part is disposed over the first surface of the printed circuit board, at least a portion of the second conducting part is disposed within the conductive hole of the printed circuit board, and the tip part is disposed under the second surface of the printed circuit board, wherein a soldering material is coated on a junction between the printed circuit board and the tip part and/or the second conducting part of the wire fixing device, so that the wire fixing device is fixed on the printed circuit board.

2. The circuit board assembly according to claim 1, wherein the wire fixing device is made of a metallic conductive material.

3. The circuit board assembly according to claim 1, wherein the second conducting part of the wire fixing device is snap-fitted or interference-fitted into the conductive hole of the printed circuit board.

4. The circuit board assembly according to claim 1, wherein the wire fixing device further comprises a connecting segment, wherein the connecting segment is connected with the first conducting part and the second conducting part, and the connecting segment is in contact with the first surface of the printed circuit board and a periphery of the conductive hole.

5. The circuit board assembly according to claim 4, wherein the connecting segment is a ring-shaped structure with an external smooth curvy surface or an external slant surface, wherein the external smooth curvy surface or the external slant surface is connected with an external surface of the first conducting part and an external surface of the second conducting part.

6. The circuit board assembly according to claim 1, wherein the tip part of the wire fixing device further comprises a second opening, and the second opening is in communication with the accommodation space.

7. The circuit board assembly according to claim 1, wherein at least one concave structure is formed in an external surface of the first conducting part of the wire fixing device, and the conducting terminal of the wire is in contact with and clamped by a bottom surface of the concave structure, so that the wire is fixed on and electrically connected with the wire fixing device.

8. The circuit board assembly according to claim 1, wherein the wire fixing device is previously tin-plated.

9. The circuit board assembly according to claim 1, wherein the conductive hole has a regular polygon profile, and the second conducting part has a cylindrical profile matching the conductive hole.

10. A wire fixing device for assisting in fixing a wire on a printed circuit board and electrically connecting the wire with the printed circuit board, the printed circuit board having a first surface and a second surface, at least one conductive hole running through the first surface and the second surface, the wire having a conducting terminal, the wire fixing device comprising:
a first conducting part with a first opening, wherein the first conducting part has a first outer diameter;
a second conducting part connected with the first conducting part, wherein the second conducting part has a second outer diameter, and the second outer diameter is smaller than the first outer diameter; and
a tip part connected with the second conducting part, wherein the tip part is a taper structure,
wherein an accommodation space is disposed within the first conducting part, the second conducting part and the tip part and in communication with the first opening for accommodating the conducting terminal of the wire, wherein the first conducting part is disposed over the first surface of the printed circuit board for fixing and connecting the conducting terminal of the wire, at least a portion of the second conducting part of the wire fixing device is snap-fitted or interference-fitted into the conductive hole of the printed circuit board, and the tip part and/or the second conducting part are fixed on the second surface of the printed circuit board via a soldering material.

11. A wire fixing method, comprising steps of:
(a) providing a printed circuit board, at least one wire and a wire fixing device, wherein the printed circuit board has a first surface and a second surface, and at least one conductive hole runs through the first surface and the second surface, wherein the wire has a conducting terminal, wherein the wire fixing device comprises a first conducting part with a first opening, a second conducting part connected with the first conducting part, and a tip part connected with the second conducting part, wherein the first conducting part has a first outer diameter, the second conducting part has a second outer diameter, the second outer diameter is smaller than the first outer diameter, and the tip part is a taper structure, wherein an accommodation space is disposed within the first conducting part, the second conducting part and the tip part and in communication with the first opening;
(b) inserting the wire fixing device into the conductive hole of the printed circuit board, wherein the first conducting part is disposed over the first surface of the printed circuit board, at least a portion of the second conducting part is disposed within the conductive hole of the printed circuit board, and the tip part is disposed under the second surface of the printed circuit board;
(c) coating a soldering material on a junction between the printed circuit board and the tip part and/or the second conducting part of the wire fixing device, so that the wire fixing device is fixed on the printed circuit board;
(d) introducing the conducting terminal of the wire into the accommodation space of the wire fixing device through the first opening of the wire fixing device; and
(e) forming at least one concave structure in an external surface of the first conducting part of the wire fixing device, so that the conducting terminal of the wire is fixed on the wire fixing device and the wire is electrically connected with the printed circuit board through the wire fixing device.

12. The wire fixing method according to claim 11, wherein the wire fixing device further comprises a connecting segment, wherein the connecting segment is connected with the first conducting part and the second conducting part, wherein in the step (b), the connecting segment is in contact with the first surface of the printed circuit board and a periphery of the conductive hole.
